(19) United States
(12) Patent Application Publication
(10) Pub. No.: US 2016/0322484 A1
(43) Pub. Date: Nov. 3, 2016

(54) Bidirectional Bipolar Transistor Structure with Field-Limiting Rings Formed by the Emitter Diffusion

(71) Applicant: Ideal Power Inc., Austin, TX (US)

(72) Inventor: Richard A. Blanchard, Los Altos, CA (US)

(73) Assignee: Ideal Power Inc., Austin, TX (US)

(21) Appl. No.: 15/083,217

(22) Filed: Mar. 28, 2016

Related U.S. Application Data
(60) Provisional application No. 62/139,380, filed on Mar. 27, 2015.
(60) Provisional application No. 62/139,407, filed on Mar. 27, 2015.

(51) Int. Cl. H01L 29/747; H01L 29/40; H01L 29/66; H01L 29/06

(52) U.S. Cl. CPC H01L 29/747; H01L 29/0623; H01L 29/0649; H01L 29/407; H01L 29/66386

(57) ABSTRACT

A symmetrically-bidirectional power bipolar transistor having, on both surfaces of a semiconductor die, an n-type emitter/collector region which is completely surrounded by a first recessed field plate, which is itself completely surrounded by a p-type region including p+ contact areas. All of the p-type region is preferably bordered and surrounded by a second recessed field plate trench. The second recessed field plate trench is itself surrounded by an n-type region which is wholly or partially made of the same diffusion as the emitter/collector regions, but which is not connected to the metallization which connects the emitter/collector regions to extermal terminals.

### CROSS-REFERENCE

Priority is claimed from US provisional applications 62/139,407 and 62/139,380, both of which are hereby incorporated by reference.

### BACKGROUND

The present application discloses new approaches to fabrication of power devices having both current-carrying and control terminals on two surfaces, and more particularly to fabrication of bidirectional bipolar transistors having separate base contact regions, as well as separate emitter/collector diffusions, on both surfaces of a monolithic semiconductor die.

Note that the points discussed below may reflect the hindsight gained from the disclosed inventions, and are not necessarily admitted to be prior art.

Bi-directional bipolar transistors or “B-TRANs” have been proposed for use as high voltage bi-directional switches, based on their low on-voltages at high current levels. One concern in the actual fabrication of a high voltage B-TRAN is the design of a termination structure capable of withstanding the rated voltage without significantly increasing the cost of the device. A number of possible high voltage termination structures exist, but the goal of this work was to determine whether there are any high voltage termination structures that can be fabricated using the same process steps as those used to fabricate the B-TRAN structure. The structure of an NPN B-TRAN device is shown in FIG. 1B while one possible circuit symbol for this device is shown in FIG. 2. An enhancement to the B-TRAN structure of FIG. 1B is shown in FIG. 3. In this figure, the trench that was filled with dielectric in FIG. 1B has a trench lined with a dielectric like silicon dioxide, and is subsequently filled with conductive polycrystalline silicon. The polycrystalline silicon electrode located in each trench is in turn electrically connected to the n-type emitter diffusion region present on at least one side of the trench. FIG. 4 shows a cross section of a B-TRAN device, including a portion of the termination region of the structure.

### A Bidirectional Bipolar Transistor Structure with Field-Limiting Rings Formed by the Emitter Diffusion

The present application teaches, among other innovations, a symmetrically-bidirectional bipolar power transistor in which all of the operative emitter/collector regions (e.g. n-type) are laterally surrounded by base contact regions (e.g. p-type), and the innermost ring of the field-limiting region is also formed by at least part of the same dopant components which go into the emitter/collector regions. Optionally the entire field-limiting region can be formed from similar ring-shaped semiconductor regions, separated e.g. by rings of recessed oxide. Optionally the rings of semiconductor material can have varying widths. The number of rings of semiconductor material in the entire field-limiting region will depend on the rated voltage, as well as on process parameters.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1A shows corresponding plan and section views of a new B-TRAN device.

FIG. 1B shows the structure of an example of a B-TRAN device.

FIG. 2 shows a possible circuit symbol for the device of FIG. 1B.

FIG. 3 shows an enhancement to the B-TRAN structure of FIG. 1B.

FIG. 4 shows a cross section of a B-TRAN device, including a portion of the termination region of the structure.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

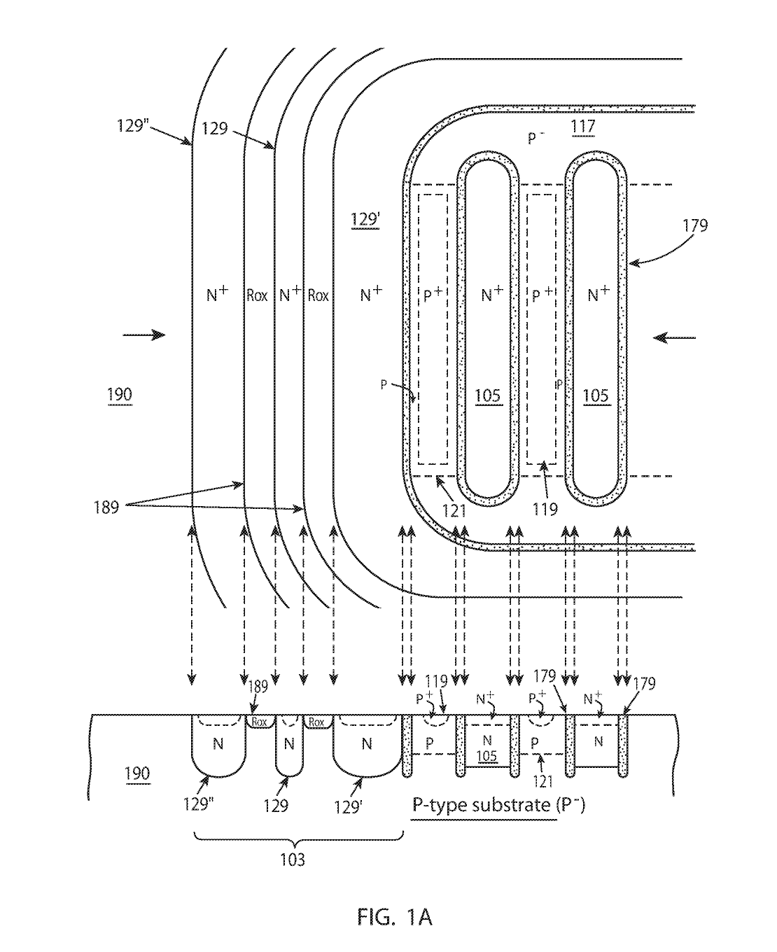

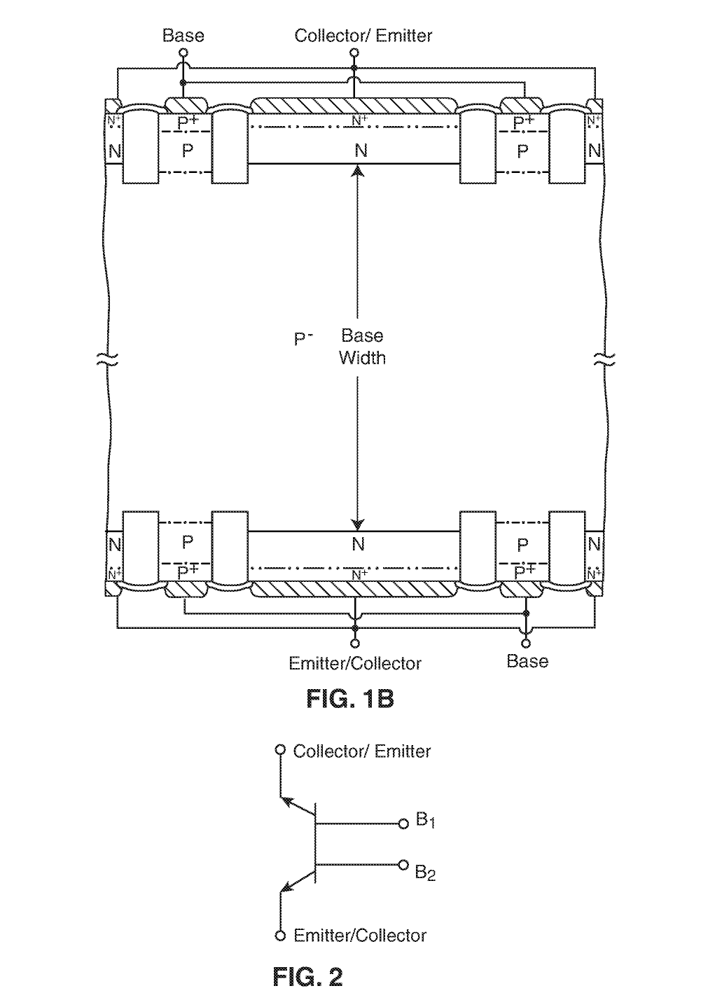

FIG. 1A shows a top view of the B-TRAN device as well as a cross section of the device. FIG. 1A shows that the termination region 103 uses the same diffused regions that form the emitter/collector regions of the B-TRAN. Specifically:

1. The diffused field-limiting rings 129 are formed by the same doping and diffusion steps as the B-TRAN emitter/collector regions 105. The use of diffused regions formed by the same step reduces the number of steps in the fabrication sequence.

2. Both the emitter regions 105 and the diffused n-type regions that form the field-limiting rings 129 preferably include both deep and shallow n-type doping components, formed by implanting both phosphorus and arsenic into the p-type substrate using the same mask. This process sequence saves the use of one masking layer, while also providing a deep n-type junction capable of withstanding a high voltage, as well as a shallow, heavily doped n++ region at the surface that forms a low resistance ohmic contact with the metal layer.

In one example, the two n-type dopants are phosphorus and arsenic, and each is implanted at a dose of 2 or 3×10¹⁵ cm⁻². Arsenic will have a shorter diffusion length than phosphorus (in silicon, for a given thermal history), so that the emitter/collector regions have both a high concentration at shallow depths, and a reasonably large junction depth.

Optionally an additional shallow n++ “plug” implant can be used to minimize specific contact resistance.

Optionally antimony can be substituted for arsenic if desired.

The example shown in FIG. 1A includes, among the field-limiting rings 129, an innermost field-limiting ring 129′ and an outermost field-limiting ring 129″. For clearer illustration, only three field-limiting rings 129 are shown in FIG. 1A, but this is simplified. In a currently preferred example, ten field-limiting rings 129 are used, including eight rings 129 between the innermost field-limiting rings 129′ and the outermost field-limiting ring 129″.

In this example, the widest one of the field-limiting rings 129 is the innermost field-limiting ring 129′. The outermost field-limiting ring 129″ is also wider than the other ones of the field-limiting rings 129.

In this example, recessed oxide regions 189 (“Rox”) are interposed between adjacent field limiting rings 129. Recessed oxide regions 189 can be formed using a “LOCOS” process, or alternatively by etching a trench, filling with oxide, and then planarizing the wafer using CMP. For example, this can be done by etching about ½ micron of silicon, growing about 1.1 micron of SiO₂, and then planarizing using CMP.

Another way to form the recessed oxide regions 189 is by etching trenches to the full desired depth of the recessed oxide regions 189 (here about 1.1 microns deep), filling the trenches using a TEOS oxide, using a modified reverse mask to remove most of the deposited oxide that is not over the trenches, and then using CMP to planarize the wafer.

In both these examples (but not necessarily in every implementation), the recessed oxide regions 189 are not associated with the field plates which can be emplaced in the trenches 179. The field plates are formed of poly silicon, later in the process.

The thickness of the recessed oxide regions 189, in this example, is selected to be slightly more than a micron. Smaller thickness values can degrade the long term reliability of the device.

Another criterion for optimization of this particular process is local planarity. Since a handle wafer will be bonded to each side of the wafer (in the preferred process), the recessed oxide regions 189 need to be planar, to avoid degrading bondability.

Another criterion for optimization of this particular process is wafer flatness. The process of forming the recessed oxide regions 189 should not impart warping or bowing of the wafer (as may be caused by accumulation of stress from local pattern features).

Note also, in FIG. 1A, that each emitter/collector region 105 is shaped like a stripe, and is bordered, along its long sides, by a p+ base contact region 119 inside p-type base contact border region 121. The short side of each emitter/collector region 105 is bordered by p− base region 117. This is useful in optimizing the emitter/collector regions to have uniform turnoff, and to have fairly uniform on-state current density across their width.

The dopant profile of the base contact regions 119 is preferably formed by several diffusion components. The background wafer doping, in this example, is p-type. In addition, two implantations of boron and/or boron difluoride dopants are used, in a preferred example, to achieve good contact resistance and reduce the series resistance from the contact area to the p-type substrate. The total p-type doping introduced into the base contact areas 119, in this example, is around 2×10¹⁵ cm⁻².

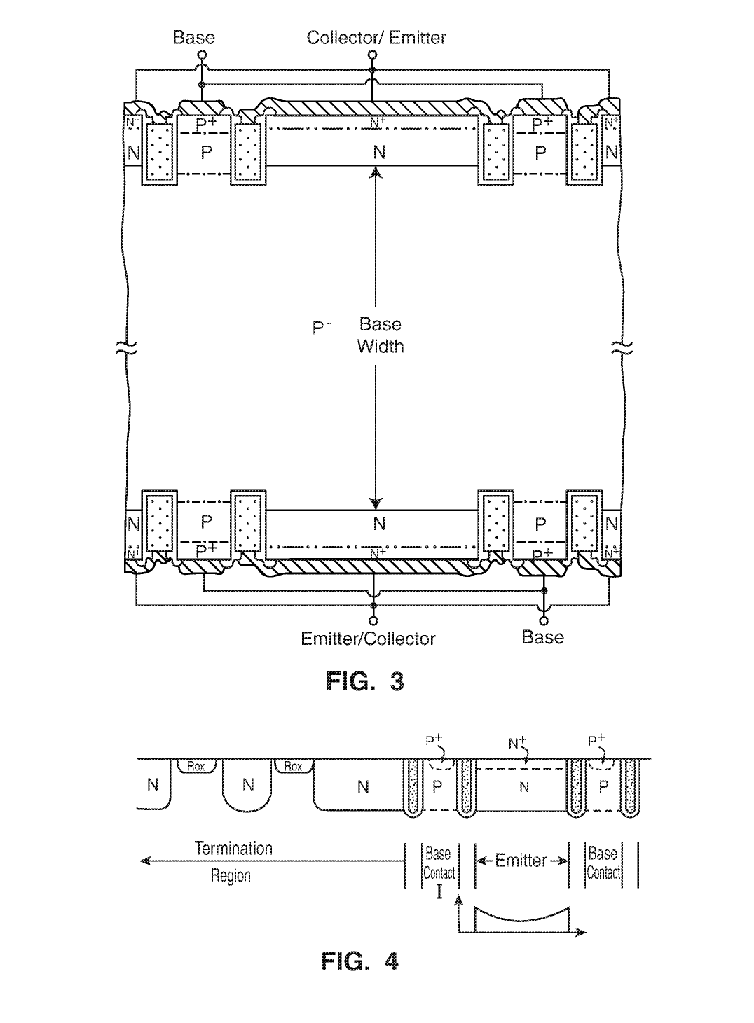

The base-to-emitter/collector isolation trenches 179, in this example, can include insulated polysilicon field plates which are electrically connected to the adjacent n-type emitter/collector region. However, other separation structures can be used, e.g. dielectric-filled trenches as shown in FIG. 3.

Note also that, in FIG. 4, the shallowest p++ diffusion stops short of borders of the base contact area 119. This keeps the lateral tail of the base contact doping from modifying the doping of the field plate in the trench 179. The p− regions are simply the doped substrate; the p regions have been implanted and diffused to about 3 microns; and the P+ regions are doped by an implant performed through the contact mask opening, to assure a low contact resistance to the P region. Thus in this example the p+ regions are set back from the poly field plate, while the p regions are not.

FIG. 1A also shows inventive features which allow for efficient mobile carrier injection when the N+/N− emitter/collector regions on one surface are forward biased (thereby acting as the emitter), and provide a high breakdown voltage when the same regions are reverse biased (and acting as the collector).

1. Each emitter/collector region is completely surrounded by a trench that has a liner of a dielectric layer or a dielectric sandwich and is filled with doped polycrystalline silicon. An electrical connection is also made between the polycrystalline silicon in the trench and the emitter region.

2. There is P+ dopant adjacent to the trench along the majority of its two straight sides. The presence of the P+ dopant in these regions provides a low resistance path to the portion of the base contact region adjacent to the emitter/collector region, thereby decreasing the base resistance. The p+ region can also be extended to completely surround the racetrack, filling the entire region between the racetracks and the poly-filled perimeter trench. (The perimeter poly-filled trench provides a transition region between the interior “active” region of the B-TRAN and the edge termination region.)

### Advantages

The disclosed innovations, in various embodiments, provide one or more of at least the following advantages. However, not all of these advantages result from every one of the innovations disclosed, and this list of advantages does not limit the various claimed inventions.
Avoidance of hot spots in the ON state;
Stable and uniform turn-off;
Ability to switch high voltages.

According to some but not necessarily all embodiments, there is provided: A symmetrically-bidirectional power bipolar transistor device, comprising: a semiconductor die having, on both surfaces thereof, a first-conductivity-type emitter/collector region; two current-carrying metallizations, on the two surfaces of the die, which separately connect the two emitter/collector regions to respective external current-carrying terminals, but not to each other; a second-conductivity-type base contact region, including heavily-doped second-conductivity-type contact areas, in proximity to the emitter/collector region; two additional metallizations, on the two surfaces of the die, which separately connect the two base contact regions to respective additional external terminals, but not to each other; one or more first-conductivity-type field-limiting rings, which in combination completely surround the emitter/collector and base contact regions; wherein each of the first-conductivity-type field-limiting rings comprises the same dopant components as the emitter/collector regions, and is not laterally continuous with any of the emitter/collector regions.

According to some but not necessarily all embodiments, there is provided: A symmetrically-bidirectional power bipolar transistor device, comprising: a semiconductor die having, on both surfaces thereof, a first-conductivity-type emitter/collector region which is completely surrounded by a first laterally-insulating trench; two current-carrying metallizations, on the two surfaces of the die, which separately connect the two emitter/collector regions to respective external current-carrying terminals, but not to each other; a second-conductivity-type base contact region, including heavily-doped second-conductivity-type contact areas, which borders and completely surrounds the first laterally-insulating trench; two additional metallizations, on the two surfaces of the die, which separately connect the two base contact regions to respective additional external terminals, but not to each other; a second laterally-insulating trench, which borders and completely surrounds the second-conductivity-type base contact region; an innermost first-conductivity-type field-limiting ring, which completely surrounds the second laterally-insulating trench; additional first-conductivity-type field-limiting rings, which surround the innermost field-limiting ring; wherein each of the first-conductivity-type field-limiting rings comprises the same dopant components as the emitter/collector regions, and is not connected to the current-carrying metallization.

According to some but not necessarily all embodiments, there is provided: A symmetrically-bidirectional power bipolar transistor device, comprising: a semiconductor die having, on both surfaces thereof, a first-conductivity-type emitter/collector region which is completely surrounded by a first recessed field plate; two current-carrying metallizations, on the two surfaces of the die, which separately connect the two emitter/collector regions to respective external current-carrying terminals, but not to each other; a second-conductivity-type base contact region, including heavily-doped second-conductivity-type contact areas, which closely borders and completely surrounds the first recessed field plate; two additional metallizations, on the two surfaces of the die, which separately connect the two base contact regions to respective additional external terminals, but not to each other; a second recessed field plate trench, which borders and completely surrounds the second-conductivity-type base contact region; an innermost first-conductivity-type field-limiting ring, which completely surrounds the second recessed field plate trench; additional first-conductivity-type field-limiting rings, which surround the innermost field-limiting ring; wherein each of the first-conductivity-type field-limiting rings comprises the same dopant components as the emitter/collector regions, and is not connected to the current-carrying metallization.

According to some but not necessarily all embodiments, there is provided: A method of fabricating a symmetrically-bidirectional power bipolar transistor device, comprising: forming one or more first-conductivity-type emitter/collector regions on both first and second sides of a second-conductivity type semiconductor wafer; forming two current-carrying metallizations, on the two sides of the wafer, which separately connect the two emitter/collector regions to respective external current-carrying terminals, but not to each other; forming second-conductivity-type base contact regions on both first and second sides of a second-conductivity-type semiconductor wafer, in proximity to the emitter/collector regions; forming two additional metallizations, on the two surfaces of the wafer, which separately connect the two base contact regions to respective additional external terminals, but not to each other; an forming first-conductivity-type field-limiting rings, on the two surfaces of the wafer, which in combination completely surround the emitter/collector and base contact regions; wherein, on each side of the wafer, the first-conductivity-type field-limiting rings and the emitter/collector regions are formed simultaneously.

According to some but not necessarily all embodiments, there is provided: A method of fabricating a symmetrically-bidirectional power bipolar transistor device, comprising: forming one or more first-conductivity-type emitter/collector regions on both first and second sides of a second-conductivity type semiconductor wafer, each surrounded by a laterally-insulating trench; forming two current-carrying metallizations, on the two sides of the wafer, which separately connect the two emitter/collector regions to respective external current-carrying terminals, but not to each other; forming second-conductivity-type base contact regions on both first and second sides of a second-conductivity type semiconductor wafer, in proximity to the respective emitter/collector regions, each being bordered and completely surrounded by a second laterally-insulating trench; forming two additional metallizations, on the two surfaces of the wafer, which separately connect the two base contact regions to respective additional external terminals, but not to each other; and forming first-conductivity-type field-limiting rings, on the two surfaces of the wafer, which in combination completely surround the emitter/collector and base contact regions; wherein, on each side of the wafer, the first-conductivity-type field-limiting rings and the emitter/collector regions are formed simultaneously.

According to some but not necessarily all embodiments, there is provided: A symmetrically-bidirectional power bipolar transistor having, on both surfaces of a semiconductor die, an n-type emitter/collector region which is completely surrounded by a first recessed field plate, which is itself completely surrounded by a p-type region including p+ contact areas. All of the p-type region is preferably bordered and surrounded by a second recessed field plate trench. The second recessed field plate trench is itself surrounded by an n-type region which is wholly or partially made of the same diffusion as the emitter/collector regions, but which is not connected to the metallization which connects the emitter/collector regions to external terminals.

According to some but not necessarily all embodiments, there is provided: a symmetrically-bidirectional bipolar power transistor in which all of the operative emitter/collector regions (e.g. n-type) are laterally surrounded by base contact regions (e.g. p-type), and the innermost ring of the field-limiting region is also formed by at least part of the same dopant components which go into the emitter/collector regions.

According to some but not necessarily all embodiments, there is provided: a symmetrically-bidirectional bipolar power transistor in which all of the operative emitter/collector regions (e.g. n-type) are laterally surrounded by base contact regions (e.g. p-type), and the innermost ring of the field-limiting region is also formed by at least part of the same dopant components which go into the emitter/collector regions; wherein the entire field-limiting region is formed from similar ring-shaped semiconductor regions, separated by rings of recessed oxide.

According to some but not necessarily all embodiments, there is provided: a symmetrically-bidirectional bipolar power transistor in which all of the operative emitter/collector regions (e.g. n-type) are laterally surrounded by base contact regions (e.g. p-type), and the innermost ring of the field-limiting region is also formed by at least part of the same dopant components which go into the emitter/collector regions; wherein the entire field-limiting region is formed from similar ring-shaped semiconductor regions of varying widths, separated by rings of recessed oxide.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

The claims as filed are intended to be as comprehensive as possible, and NO subject matter is intentionally relinquished, dedicated, or abandoned.

1. A symmetrically-bidirectional power bipolar transistor device, comprising:
a semiconductor die having, on both surfaces thereof, a first-conductivity-type emitter/collector region;
two current-carrying metallizations, on the two surfaces of the die, which separately connect the two emitter/collector regions to respective external current-carrying terminals, but not to each other;
a second-conductivity-type base contact region, including heavily-doped second-conductivity-type contact areas, in proximity to the emitter/collector region;
two additional metallizations, on the two surfaces of the die, which separately connect the two base contact regions to respective additional external terminals, but not to each other;
one or more first-conductivity-type field-limiting rings, which in combination completely surround the emitter/collector and base contact regions;
wherein each of the first-conductivity-type field-limiting rings comprises the same dopant components as the emitter/collector regions, and is not laterally continuous with any of the emitter/collector regions.

2. The device of claim 1, wherein the emitter/collector region defines a junction therebeneath, and the base contact regions have a depth similar to that of the emitter/collector regions.

3. The device of claim 1, wherein the wafer is silicon.

4. The device of claim 1, wherein the first type is n-type.

5. The device of claim 1, further comprising isolation trenches which, on each surface, laterally separate the base contact region from the emitter/collector region.

6. The device of claim 1, further comprising trenched insulated field plates which, on each surface, laterally separate the base contact region from the emitter/collector region.

7. The device of claim 1, comprising more than six of the first-conductivity-type field-limiting rings.

8. The device of claim 1, wherein adjacent pairs of the first-conductivity-type field-limiting rings are laterally separated by rings having dielectric material at the surface thereof.

9. A symmetrically-bidirectional power bipolar transistor device, comprising:
a semiconductor die having, on both surfaces thereof, a first-conductivity-type emitter/collector region which is completely surrounded by a first laterally-insulating trench;
two current-carrying metallizations, on the two surfaces of the die, which separately connect the two emitter/collector regions to respective external current-carrying terminals, but not to each other;
a second-conductivity-type base contact region, including heavily-doped second-conductivity-type contact areas, which borders and completely surrounds the first laterally-insulating trench;
two additional metallizations, on the two surfaces of the die, which separately connect the two base contact regions to respective additional external terminals, but not to each other;
a second laterally-insulating trench, which borders and completely surrounds the second-conductivity-type base contact region;
an innermost first-conductivity-type field-limiting ring, which completely surrounds the second laterally-insulating trench;
additional first-conductivity-type field-limiting rings, which surround the innermost field-limiting ring;
wherein each of the first-conductivity-type field-limiting rings comprises the same dopant components as the emitter/collector regions, and is not connected to the current-carrying metallization.

10. The device of claim 9, wherein the emitter/collector region defines a junction therebeneath, and the base contact regions have a depth similar to that of the emitter/collector regions.

11. The device of claim 9, wherein the wafer is silicon.

12. The device of claim 9, wherein the first type is n-type.

13. The device of claim 9, wherein the laterally-insulating trenches have insulated field plates therein.

14. The device of claim 9, comprising more than six of the first-conductivity-type field-limiting rings.

15. A symmetrically-bidirectional power bipolar transistor device, comprising:
a semiconductor die having, on both surfaces thereof, a first-conductivity-type emitter/collector region which is completely surrounded by a first recessed field plate;
two current-carrying metallizations, on the two surfaces of the die, which separately connect the two emitter/collector regions to respective external current-carrying terminals, but not to each other;
a second-conductivity-type base contact region, including heavily-doped second-conductivity-type contact areas, which closely borders and completely surrounds the first recessed field plate;
two additional metallizations, on the two surfaces of the die, which separately connect the two base contact regions to respective additional external terminals, but not to each other;
a second recessed field plate trench, which borders and completely surrounds the second-conductivity-type base contact region;
an innermost first-conductivity-type field-limiting ring, which completely surrounds the second recessed field plate trench;
additional first-conductivity-type field-limiting rings, which surround the innermost field-limiting ring;
wherein each of the first-conductivity-type field-limiting rings comprises the same dopant components as the emitter/collector regions, and is not connected to the current-carrying metallization.

16. The device of claim 15, wherein the emitter/collector region defines a junction therebeneath, and the base contact regions have a depth similar to that of the emitter/collector regions.

17. The device of claim 15, wherein the wafer is silicon.

18. The device of claim 15, wherein the first type is n-type.

19. The device of claim 15, comprising more than six of the first-conductivity-type field-limiting rings.

20-21. (canceled)
